(19) United States
(12) Patent Application Publication
(10) Pub. No.: US 2011/0242960 A1
(43) Pub. Date: Oct. 6, 2011

(54) LIGHT EMITTING DEVICE AND METHOD FOR MANUFACTURING LIGHT EMITTING DEVICE

(76) Inventors: Toshiaki Takasu, Osaka (JP); Seiji Hoshi, Osaka (JP); Yoshiyuki Hashimoto, Osaka (JP); Takeshi Ohta, Osaka (JP); Toshiyasu Tanaka, Osaka (JP); Noriaki Terahara, Osaka (JP); Yasuo Ueda, Osaka (JP)

(21) Appl. No.: 12/974,968

(22) Filed: Dec. 21, 2010

(30) Foreign Application Priority Data
Dec. 25, 2009 (JP) 2009-294159

(51) Int. Cl. G11B 7/125; F21V 21/00; H05K 3/30

(52) U.S. Cl. 369/121; 362/382; 29/832; G9B/7.098

(57) ABSTRACT

A light emitting device includes a base, a light-emitting module, and a shielding case. The light-emitting module is fixed to the base via a curved flexible printed-circuit. The shielding case fixed to the base in such a manner that the light-emitting module is held in a position to resist a restoring force of the flexible printed-circuit which is generated by the curve of the flexible printed-circuit. The light-emitting module includes a heat source, and the shielding case includes a projection. The projection controls movement of the light-emitting module in a direction perpendicular to the direction in which the light-emitting module is held by the shielding case. The projection and the light-emitting module are bonded to each other with silicone.

### RELATED APPLICATIONS

This application claims priority under 35 U.S.C. §119 to Japanese Patent Application No. 2009-294159 filed on Dec. 25, 2009, the entire content of which is hereby incorporated by reference.

### BACKGROUND OF THE INVENTION

1. Field of the Invention

The present disclosure relates to a light emitting device used in a device for recording and reproducing information recording media such as optical discs, and also relates to a method for manufacturing the light emitting device.

2. Background Art

The light emitting device used in the device for recording and reproducing information recording media includes a light-emitting laser element and an object lens. The light-emitting laser element emits a laser beam, and the object lens collects the laser beam and focuses it on the signal recording surface of an information recording medium. In the light emitting device, information signals are recorded by forming recording marks on an information recording medium, and are reproduced by making a light detector receive the laser beam reflected by the signal recording surface.

With the recent increase in record reproduction speed and recording density, light-emitting laser elements used in light emitting devices are being required to have high power output. In conventional light emitting devices, however, light-emitting laser elements generate an excessive amount of heat, thereby degrading the light-emitting laser elements and shortening their useful life. The excessive amount of heat also degrades the quality and performance of optical components used in the light-emitting laser elements.

### BRIEF SUMMARY OF THE INVENTION

An object of the present disclosure is to provide a light emitting device which efficiently releases heat from a light-emitting laser element, and a method for easily manufacturing a light emitting device.

The light emitting device of the present disclosure includes a base, a light-emitting module, and a shielding case. The light-emitting module includes a heat source, and is fixed to the base via a curved flexible printed-circuit (FPC). The shielding case is fixed to the base in such a manner that the light-emitting module is held in a position to resist a restoring force of the FPC, which is generated by the curve of the FPC. The shielding case includes a projection, which controls movement of the light-emitting module in a direction perpendicular to the direction in which the light-emitting module is held by the shielding case. The projection and the light-emitting module are bonded to each other with silicone.

According to this structure, the light emitting device of the present disclosure efficiently releases heat from the light-emitting laser element.

The method of the present disclosure for manufacturing a light emitting device includes first, second, third, and fourth steps. The light emitting device to be manufactured according to the method of the present disclosure includes a base, a light-emitting module, and a shielding case. The light-emitting module is fixed to the base via a FPC, and the shielding case is fixed to the base. The shielding case includes a projection, which is bonded to the light-emitting module with silicone. The first step is a step of fixing the FPC having the light-emitting module to the base. The second step is a step of fixing the shielding case to the base. In this step, the FPC is bent, and the shielding case holds the light-emitting module in a position to resist a restoring force of the FPC, which is generated by the curve of the FPC. The projection controls movement of the light-emitting module in a direction perpendicular to a direction in which the light-emitting module is held by the shielding case. The third step is a step of positioning the light-emitting module with respect to the base. The fourth step is a step of bonding the projection and the light-emitting module to each other with silicone.

According to the method of the present disclosure, the light emitting device is manufactured easily.

### BRIEF DESCRIPTION OF THE DRAWINGS

FIG. 1 is a perspective view of an optical pickup of a first embodiment when viewed from its top surface.

FIG. 2 is a perspective view of the optical pickup of the first embodiment when viewed from its bottom surface.

FIG. 3 is an enlarged perspective view of a light-emitting module and its peripheral region in the optical pickup of the first embodiment when viewed from its bottom surface.

FIG. 4 is an exploded perspective view of the light-emitting module and its peripheral region in the optical pickup of the first embodiment when viewed from its bottom surface.

FIG. 5 is a sectional view of a dual-wavelength LD holder and its peripheral region in the optical pickup of the first embodiment, taken along a line I-I shown in FIG. 3.

FIG. 6 is a sectional view of the dual-wavelength LD holder and its peripheral region in the optical pickup of the first embodiment, taken along a line II-II shown in FIG. 3.

FIG. 7 is a flowchart showing a method for manufacturing the optical pickup of the first embodiment.

FIGS. 8A-8D show manufacturing processes of the dual-wavelength LD holder and its peripheral region in the optical pickup of the first embodiment, taken along the line I-I shown in FIG. 3.

FIGS. 9A-9D show manufacturing processes of the dual-wavelength LD holder and its peripheral region in the optical pickup of the first embodiment, taken along the line II-II shown in FIG. 3.

FIG. 10 is a graph showing advantages of the optical pickup of the first embodiment.

FIG. 11 is an enlarged perspective view of a dual-wavelength LD holder and its peripheral region in an optical pickup of a second embodiment when viewed from its bottom surface.

FIG. 12 is a sectional view of the dual-wavelength LD holder and its peripheral region in the optical pickup of the second embodiment, taken along a line I-I shown in FIG. 11.

FIG. 13 is an enlarged perspective view of a dual-wavelength LD holder and its peripheral region in an optical pickup of a third embodiment when viewed from its bottom surface.

FIG. 14 is a sectional view of the dual-wavelength LD holder and its peripheral region in the optical pickup of the third embodiment, taken along a line I-I shown in FIG. 13.

### DETAILED DESCRIPTION OF PREFERRED EMBODIMENTS

### First Embodiment

### 1. Structure of Optical Pickup 1

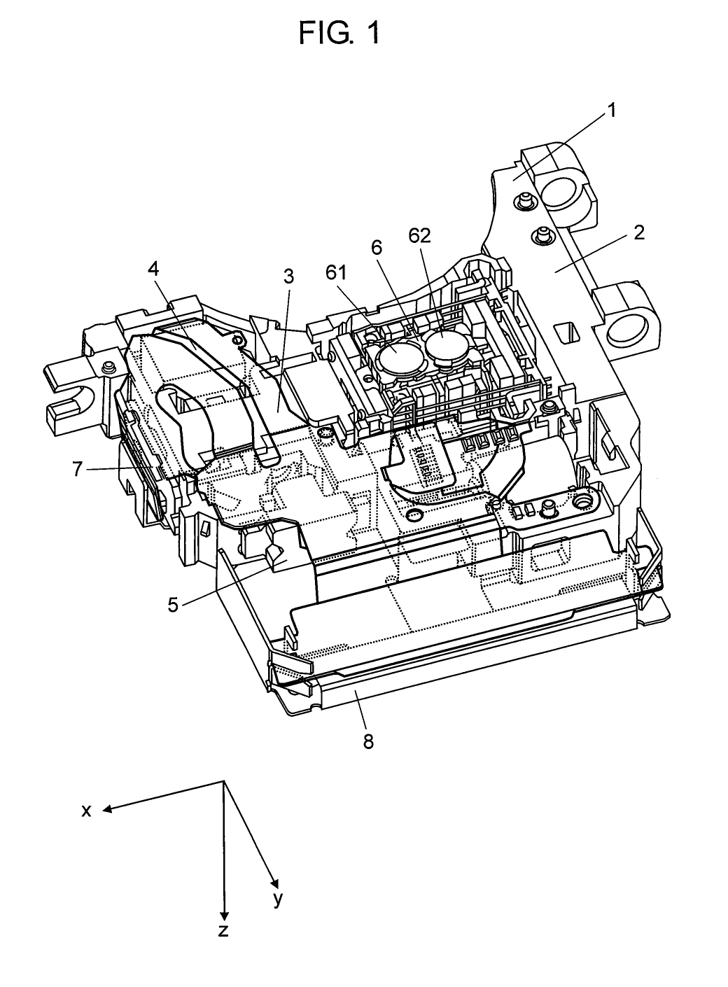

As shown in FIG. 1, optical pickup 1 includes base 2, FPC 3, dual-wavelength LD (laser diode) holder 4, blue-wavelength LD holder 5, actuator 6, PDIC (photo detector integrated circuit) holder 7, and shielding case 8. Dual-wavelength LD holder 4 and blue-wavelength LD holder 5 are light-emitting modules each having a light-emitting laser element.

Optical pickup 1 is provided in an optical disc player, an optical disc recorder, or the like so as to read and record information from/into an optical disc.

Base 2, which is made of a resin material, is mounted with components of optical pickup 1.

FPC 3 is fixed to base 2 and electrically connects these components of optical pickup 1.

Dual-wavelength LD holder 4, which is fixed to base 2 via FPC 3, emits a laser beam for a CD (compact disc), and a laser beam for a DVD (digital versatile disc). The structure and attachment of dual-wavelength LD holder 4 will be described in detail later.

Blue-wavelength LD holder 5 has a blue-wavelength LD, which is a light-emitting laser element. The blue-wavelength LD emits a laser beam for a BD (Blu-ray Disc (trademark)).

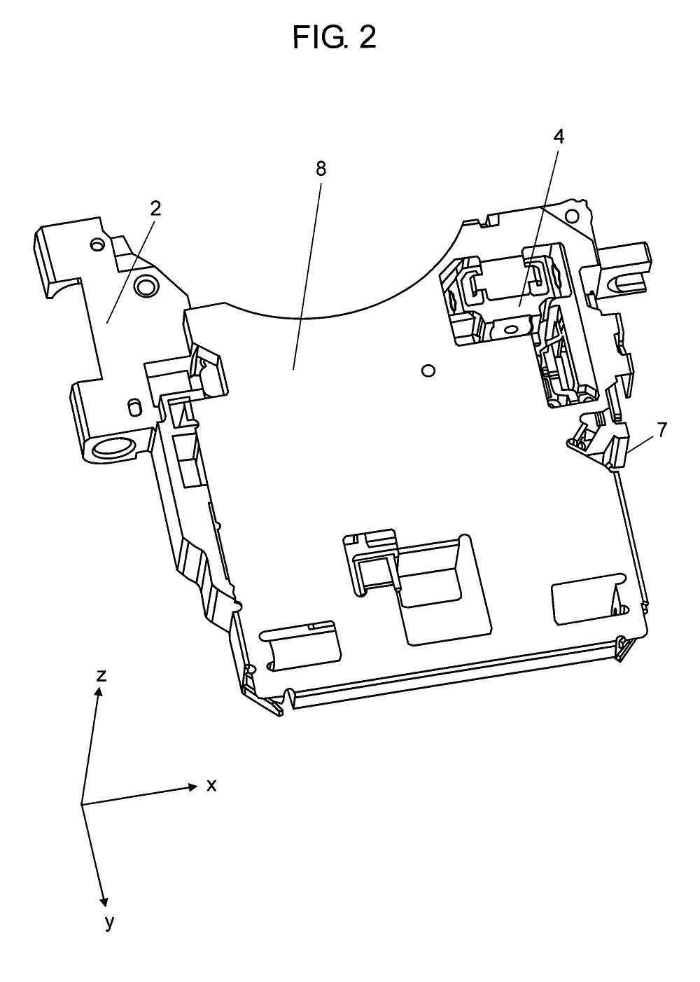

Actuator 6 includes infrared- and red-wavelength object lens 61 and blue-wavelength object lens 62, and applies the laser beams emitted from dual-wavelength LD holder 4 or blue-wavelength LD holder 5 to the optical disc. As shown in FIGS. 1 and 2, optical pickup 1 of the first embodiment has infrared- and red-wavelength object lens 61 and blue-wavelength object lens 62 on its top surface side. In other words, the top surface side is the side from which the laser beams are emitted. The side opposite to the top surface side is the bottom surface side.

PDIC holder 7 includes a PDIC, which receives a laser beam reflected by the optical disc, and converts the received laser beams into electrical signals.

As shown in FIG. 2, shielding case 8 is fixed to the bottom surface of base 2 with claws, screws, or other fixing devices. Shielding case 8 is made of a metal material with higher thermal conductivity than resin materials.

### 2. Structure of Dual-Wavelength LD Holder 4

As shown in FIG. 3, dual-wavelength LD holder 4 is fixed to base 2 with adhesive 10, and is bonded to shielding case 8 with silicone 9. Shielding case 8 includes cover 81 and projections 82. Cover 81 covers the bottom surface of dual-wavelength LD holder 4, and projections 82 project from cover 81 toward dual-wavelength LD holder 4. Projections 82 are in close contact with silicone 9.

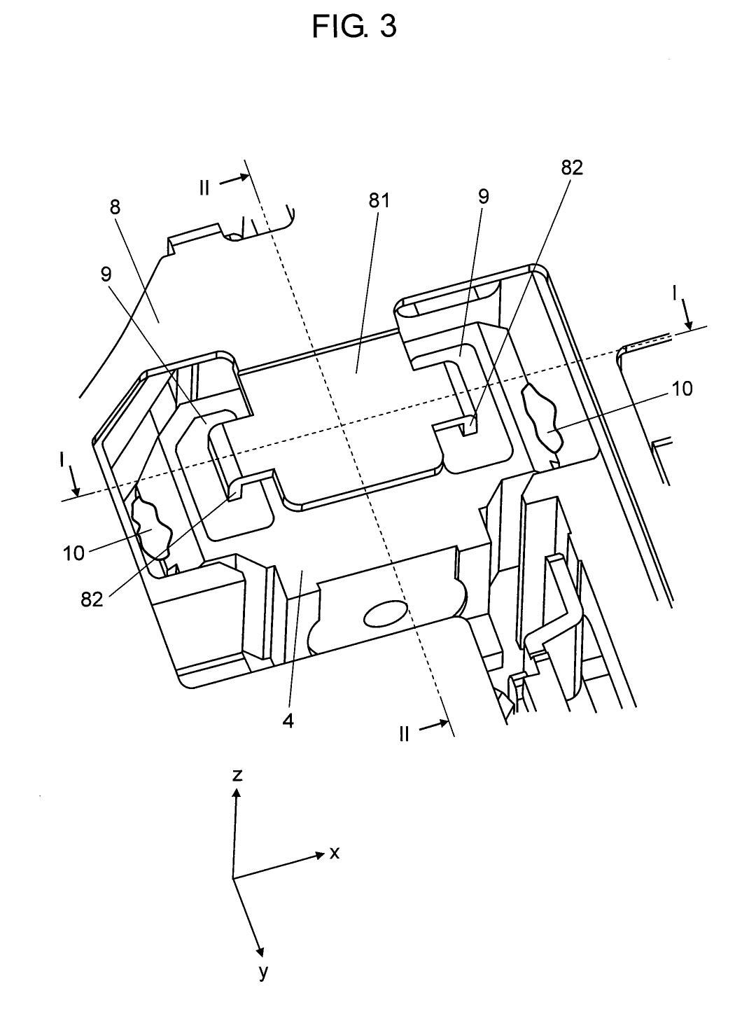

As shown in FIG. 4, dual-wavelength LD holder 4 is provided on its bottom surface with two depressions 41 into which projections 82 are inserted.

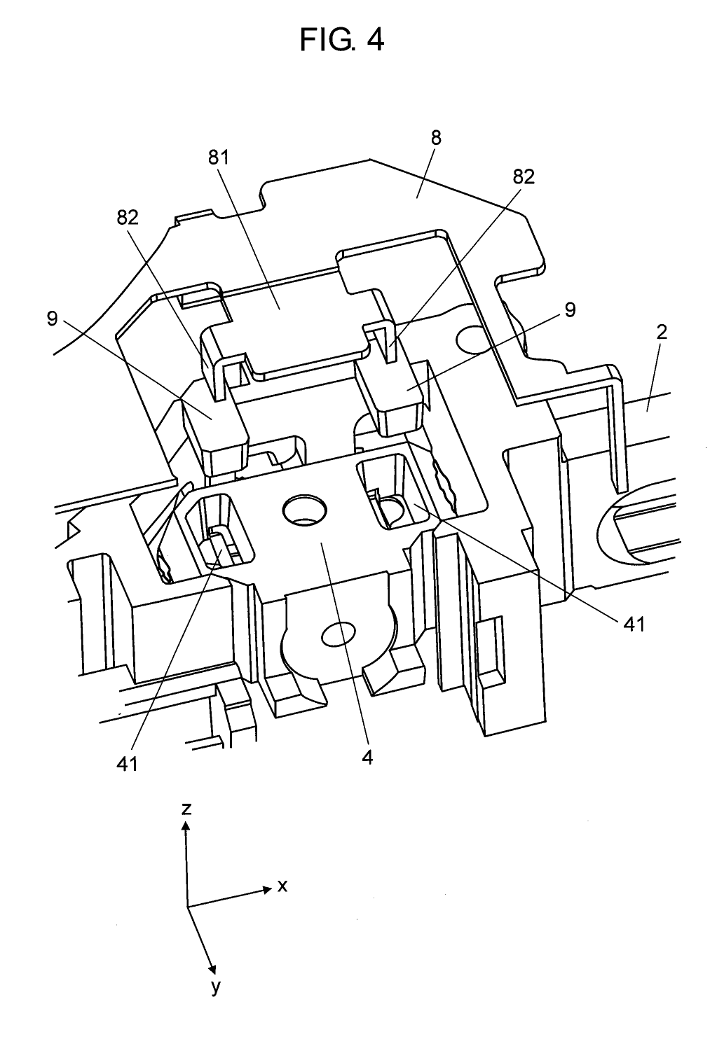

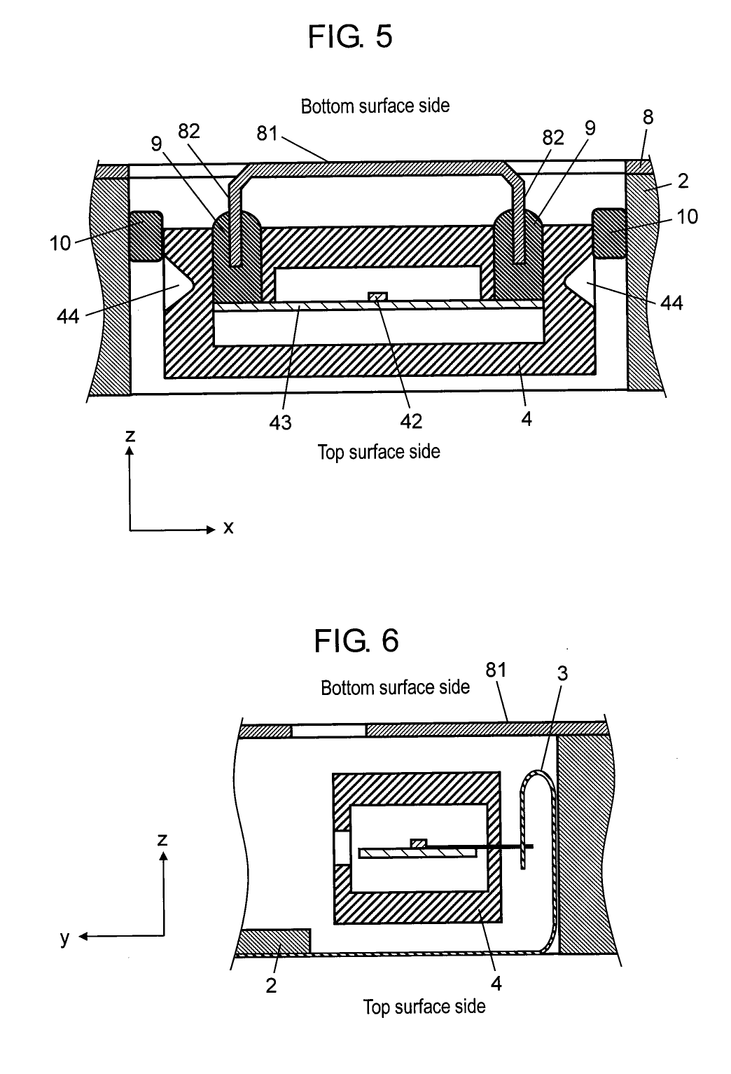

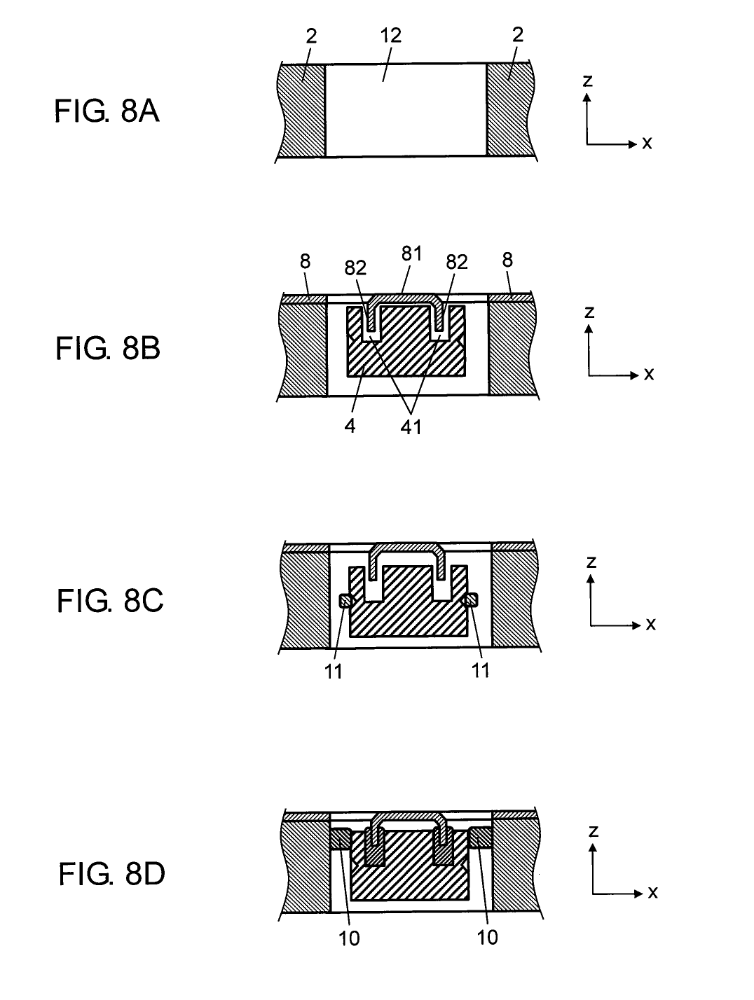

As shown in FIG. 5, silicone 9 is injected into depressions 41 with projections 82 inserted therein. In other words, projections 82 and dual-wavelength LD holder 4 are bonded to each other with silicone 9. Dual-wavelength LD holder 4 is provided inside with metal sheet 43 and dual-wavelength LD 42 placed on metal sheet 43. Dual-wavelength LD 42 is a light-emitting laser element as a heat source, and emits an infrared-wavelength laser beam and a red-wavelength laser beam. Metal sheet 43 forms one surface of depressions 41, and is in close contact with silicone 9. Dual-wavelength LD holder 4 includes V-shaped grooves 44 in order to adjust the optical axes of the laser beams emitted from dual-wavelength LD 42. V-shaped grooves 44 are held by chuck pins 11. Dual-wavelength LD holder 4 is positioned by chuck pins 11 (see FIG. 8C).

Thus, in the first embodiment, dual-wavelength LD 42 as a heat source is connected to shielding case 8 via metal sheet 43 and silicone 9. Inserting projections 82 into depressions 41 reduces the distance between dual-wavelength LD 42 and shielding case 8, allowing the heat generated in dual-wavelength LD 42 to be released efficiently to the outside of dual-wavelength LD holder 4. Inserting projections 82 into depressions 41 also controls movement of dual-wavelength LD holder 4, particularly in the x- and y-axis directions shown in FIGS. 1 to 5 during manufacture of optical pickup 1. The x- and y-axis directions shown in FIGS. 1 to 5 are perpendicular to the z-axis direction corresponding to the bottom surface side when viewed from base 2.

As shown in FIG. 6, dual-wavelength LD holder 4 is fixed to base 2 via curved FPC 3, and is therefore subjected to a restoring force of FPC 3 in the z-axis direction. Cover 81 of shielding case 8 is located in a position to control movement of dual-wavelength LD holder 4 in the z-axis direction. In other words, shielding case 8 is fixed to base 2 in such a manner that dual-wavelength LD holder 4 is held in a position to resist the restoring force of FPC 3 which is generated by the curve of FPC 3. Dual-wavelength LD 42 is connected to a wire of FPC 3 so as to be supplied with power via FPC 3.

With the above-described structure, optical pickup 1 has quality and characteristics which allow efficient release of the heat of dual-wavelength LD 42, thereby preventing a temperature increase in the light-emitting laser elements. Preventing the temperature increase in the light-emitting laser elements can avoid the problem of unstable operation of optical pickup 1 due to high temperature, and also the problem of the degradation and short life of the light-emitting laser elements.

With the above-described structure, during manufacture of optical pickup 1, dual-wavelength LD holder 4 is restricted in its movement before it is fixed to base 2. This allows manufactures to easily insert chuck pins 11 into V-shaped grooves 44. In other words, this facilitates the step of positioning dual-wavelength LD holder 4.

Shielding case 8 is made of a metal material in terms of cost and heat-release characteristics in the first embodiment, but may alternatively be made of a resin material with high thermal conductivity. Silicone 9 is preferably made of thermal grease or resin adhesive with high thermal conductivity in terms of workability and cost.

### 3. Manufacture of Optical Pickup 1

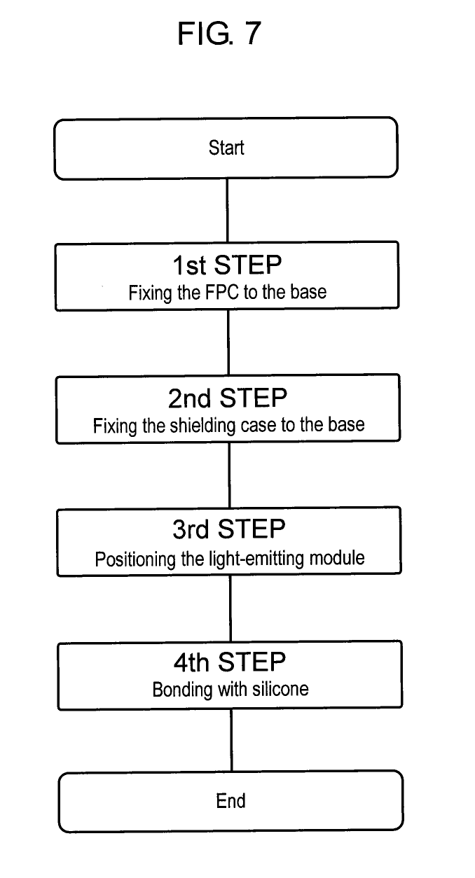

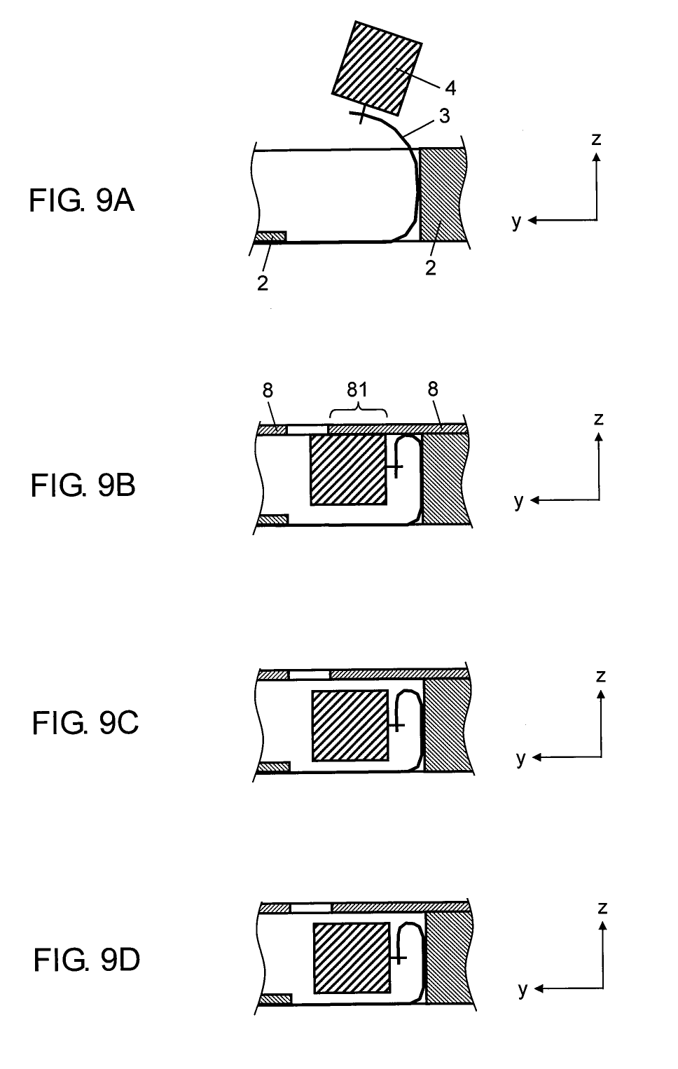

The method for manufacturing optical pickup 1 includes a step of fixing dual-wavelength LD holder 4. In this step, flexible printed-circuit 3, dual-wavelength LD holder 4, and shielding case 8 are fixed to base 2 with silicone 9 and adhesive 10. As shown in FIG. 7, the step of fixing dual-wavelength LD holder 4 includes first, second, third, and fourth steps. FIGS. 8A-8D and 9A-9D show manufacturing processes corresponding to these steps.

The first step is a step of fixing FPC 3 to base 2. As shown in FIG. 9A, FPC 3 with dual-wavelength LD holder 4 is fixed to base 2. In this step, the movement of dual-wavelength LD holder 4 is controlled only by FPC 3.

The second step is a step of fixing shielding case 8 to base 2. First, in FIG. 9B, dual-wavelength LD holder 4 is accommodated in hollow 12 of base 2. At this moment, FPC 3 is bent to generate a restoring force in the z-axis direction. Next, shielding case 8 is fixed to base 2. At this moment, dual-wavelength LD holder 4 is held by cover 81 in a position to resist the restoring force of FPC 3 which is generated by the curve of FPC 3. In FIG. 8B, projections 82 are inserted into depressions 41. As a result, cover 81 controls movement of dual-wavelength LD holder 4 in the direction (the z-axis direction) of the restoring force of curved FPC 3 which is applied to dual-wavelength LD holder 4. Furthermore, projections 82 control movement of dual-wavelength LD holder 4 in the x- and y-axis directions which are perpendicular to the z-axis direction. Projections 82 may be longer or shorter in length than the depth of depressions 41. When projections 82 are longer in length than the depth of depressions 41, the ends of projections 82 come into contact with the bottom surface of depressions, thereby controlling movement of dual-wavelength LD holder 4 in the z-axis direction.

The third step is a step of positioning dual-wavelength LD holder 4 with respect to base 2. In FIG. 8C, dual-wavelength LD holder 4 is held by chuck pins 11 in the position of V-shaped grooves 44. Next, dual-wavelength LD holder 4 is positioned so that the laser beams emitted from dual-wavelength LD 42 are collected and focused on predetermined positions of the PDIC of PDIC holder 7. Then, adhesive 10 is injected between base 2 and dual-wavelength LD holder 4. Thus, dual-wavelength LD holder 4 is fixed to base 2.

The fourth step is a step of bonding projections 82 and dual-wavelength LD holder 4 to each other with silicone 9. In the first embodiment, silicone 9 is injected into depressions 41 with projections 82 inserted therein. Thus, dual-wavelength LD 42 and shielding case 8 are connected to each other via metal sheet 43 and silicone 9.

Thus, according to the method of the first embodiment for manufacturing optical pickup 1, shielding case 8 restricts movement of dual-wavelength LD holder 4 before it is fixed to base 2. This allows manufactures to easily insert chuck pins 11 into V-shaped grooves 44. In other words, this facilitates the step of positioning dual-wavelength LD holder 4.

### 4. Operation of Optical Pickup 1

Dual-wavelength LD 42 in dual-wavelength LD holder 4 emits an infrared-wavelength laser beam and a red-wavelength laser beam. The laser beams thus emitted are collected and focused on a recording/reproducing surface of an optical disc such as a CD or a DVD through infrared- and red-wavelength object lens 61 of actuator 6. The focused laser beams are reflected by the recording/reproducing surface of the optical disc, and incident on PDIC holder 7. The incident laser beams are converted into electrical signals by the PDIC of PDIC holder 7. Similarly, the blue-wavelength LD of blue-wavelength LD holder 5 emits a blue-wavelength laser beam. The emitted laser beam is collected and focused on the recording/reproducing surface of the optical disc such as a BD through blue-wavelength object lens 62 of actuator 6, reflected by the recording/reproducing surface, and incident on PDIC holder 7. The incident laser beams are converted into electrical signals by the PDIC of PDIC holder 7.

Thus, optical pickup 1 reads and records information from/into the optical disc.

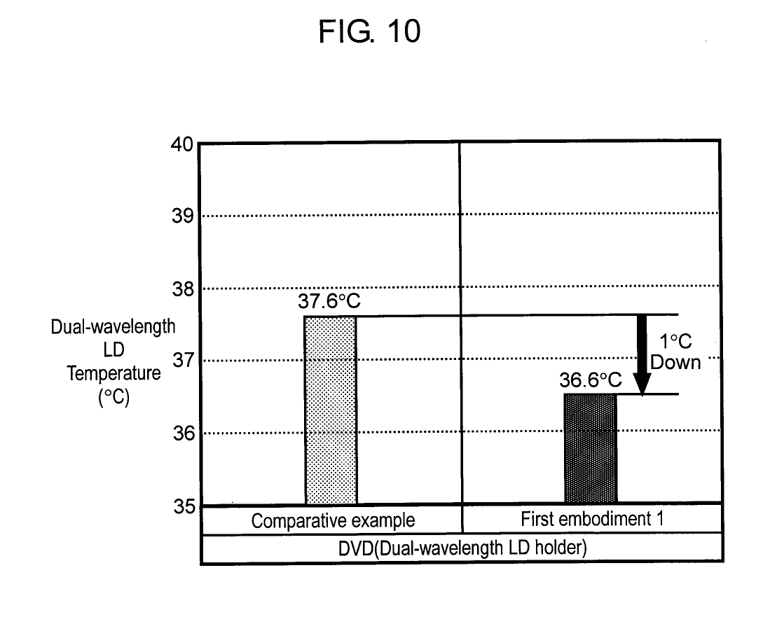

The inventors of the present disclosure have measured the temperature of dual-wavelength LD holder 4 in order to confirm the effect of heat release of optical pickup 1 of the first embodiment. The temperature measurement has been performed when the DVD has been played for a predetermined time in the recording/reproducing device in which optical pickup 1 is used. As a comparative example, an optical pickup has been used in which cover 81 does not include projections 82. As shown in FIG. 10, the temperature of optical pickup 1 of the first embodiment is lower by 1° C. than that of the comparative example.

### Second Embodiment

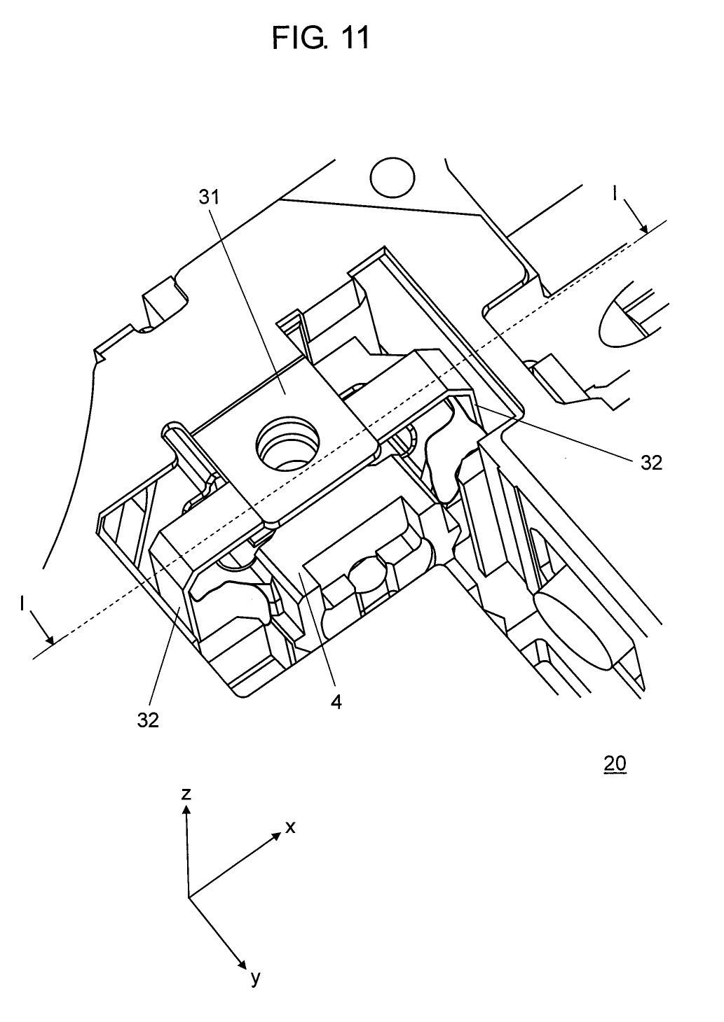

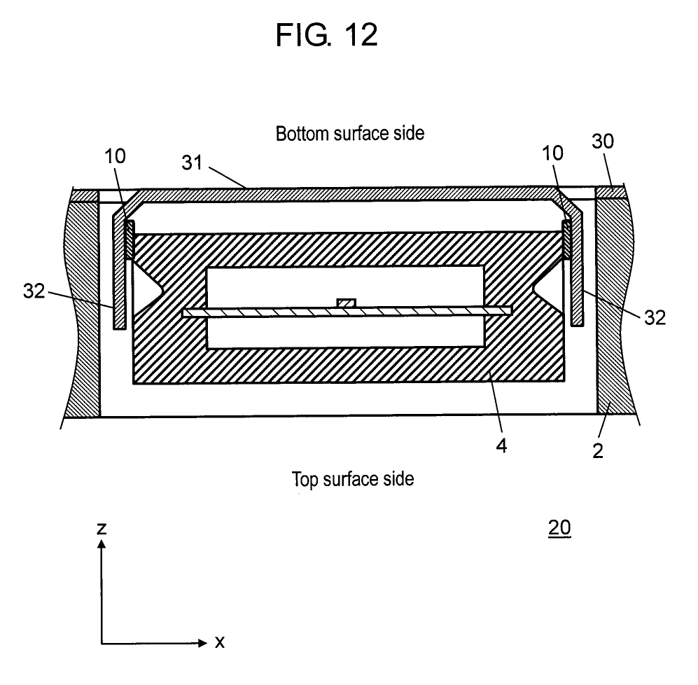

As shown in FIGS. 11 and 12, optical pickup 20 of a second embodiment has the same basic structure as optical pickup 1 of the first embodiment. The following description will be directed to the features of optical pickup 20 that are different from optical pickup 1.

In FIGS. 11 and 12, optical pickup 20 includes shielding case 30 having cover 31. Cover 31 holds dual-wavelength LD holder 4 in a position to resist the restoring force of FPC 3 which is generated by the curve of FPC 3. Shielding case 30 includes projections 32, which project from cover 31 toward dual-wavelength LD holder 4. Projections 32 project between dual-wavelength LD holder 4 and base 2 so as to reduce the distance between dual-wavelength LD 42 and shielding case 30. As a result, the heat generated in dual-wavelength LD 42 can be released efficiently to the outside of dual-wavelength LD holder 4. Projecting projections 32 between dual-wavelength LD holder 4 and base 2 also controls movement of dual-wavelength LD holder 4, particularly in the x- and z-axis directions shown in FIG. 11 during manufacture of optical pickup 20. The movement of dual-wavelength LD holder 4 is not controlled in the y-axis direction shown in FIG. 11, that is, in the direction in which dual-wavelength LD holder 4 emits laser beams. However, chuck pins 11 support dual-wavelength LD holder 4 in the direction of the laser beams, thereby improving workability.

### Third Embodiment

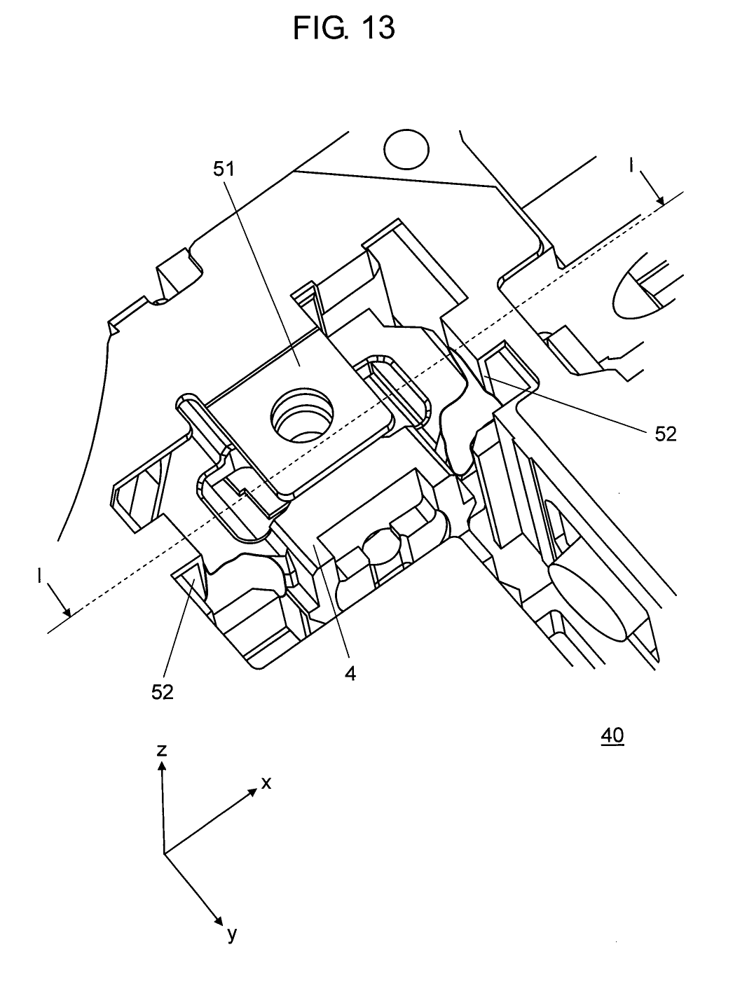

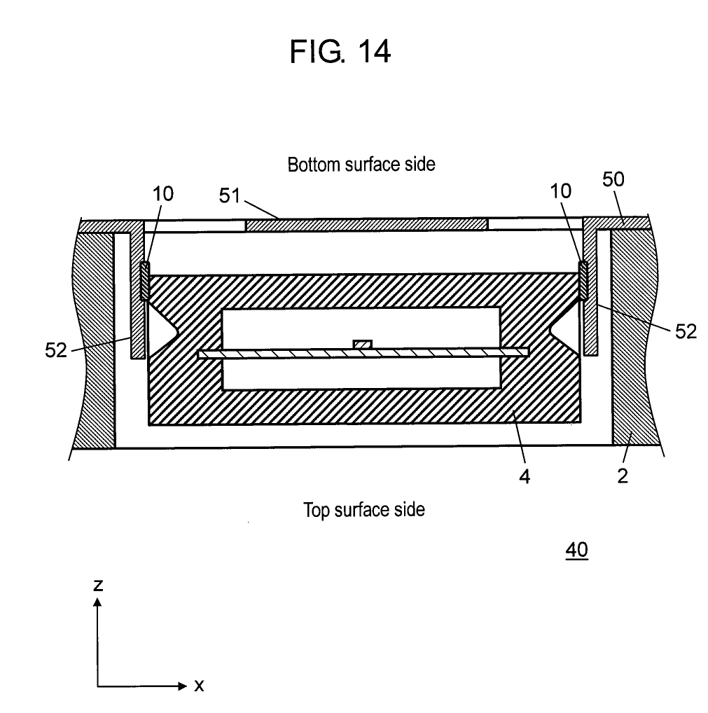

In FIGS. 13 and 14, optical pickup 40 of a third embodiment has the same basic structure as optical pickup 1 of the first embodiment. The following description will be directed to the features of optical pickup 40 that are different from optical pickup 1.

As shown in FIGS. 13 and 14, optical pickup 40 includes shielding case 50 having cover 51. Cover 51 holds dual-wavelength LD holder 4 in a position to resist the restoring force of FPC 3 which is generated by the curve of FPC 3. Shielding case 50 includes projections 52, which project from portions other than cover 51 toward dual-wavelength LD holder 4. Projections 52 project between dual-wavelength LD holder 4 and base 2 so as to reduce the distance between dual-wavelength LD 42 and shielding case 50. As a result, the heat generated in dual-wavelength LD 42 can be released efficiently to the outside of dual-wavelength LD holder 4. Projecting projections 52 between dual-wavelength LD holder 4 and base 2 also controls movement of dual-wavelength LD holder 4, particularly in the x- and z-axis directions shown in FIG. 13 during manufacture of optical pickup 40. The movement of dual-wavelength LD holder 4 is not controlled in the y-axis direction shown in FIG. 13, that is, in the direction in which dual-wavelength LD holder 4 emits laser beams. However, chuck pins 11 support dual-wavelength LD holder 4 in the direction of the laser beams, thereby improving workability.

What is claimed is:

1. A light emitting device comprising:
a base;
a light-emitting module fixed to the base via a curved flexible printed-circuit; and
a shielding case fixed to the base in such a manner that the light-emitting module is held in a position to resist a restoring force of the flexible printed-circuit, the restoring force being generated by a curve of the flexible printed-circuit, wherein
the light-emitting module includes a heat source;
the shielding case includes a projection controlling movement of the light-emitting module in a direction perpendicular to a direction in which the light-emitting module is held by the shielding case, and
the projection and the light-emitting module are bonded to each other with silicone.

2. The light emitting device of claim 1, wherein
the light-emitting module comprises:
a light-emitting laser element as the heat source; and
a metal sheet having the light-emitting laser element, the metal sheet being bonded to the projection with the silicone.

3. The light emitting device of claim 1, wherein
the light-emitting module includes a depression into which the projection is inserted.

4. An optical pickup including the light emitting device of claim 1, comprising:
a light-emitting laser element as the heat source;
an actuator for applying a laser beam emitted from the light-emitting laser element to an optical disc; and
a light detector for receiving the laser beam reflected by the optical disc.

5. A method for manufacturing a light emitting device including a base; a light-emitting module fixed to the base via a flexible printed-circuit; and a shielding case fixed to the base, the shielding case having a projection bonded to the light-emitting module with silicone, the method comprising:
fixing the flexible printed-circuit having the light-emitting module to the base;
bending the flexible printed-circuit and fixing the shielding case to the base in such a manner that the light-emitting module is held in a position to resist a restoring force of the flexible printed-circuit, the restoring force being generated by a curve of the flexible printed-circuit, and that the projection controls movement of the light-emitting module in a direction perpendicular to a direction in which the light-emitting module is held by the shielding case;
positioning the light-emitting module with respect to the base; and
bonding the projection and the light-emitting module to each other with silicone.

6. The method of claim 5, wherein
the light-emitting module includes a depression;
the projection is inserted into the depression; and
the silicone is injected into the depression with the projection inserted therein.
